(19) United States
(12) Patent Application Publication
(10) Pub. No.: US 2012/0176737 A1
(43) Pub. Date: Jul. 12, 2012

(54) Display device

(76) Inventors: Min-Ki Kim, Yongin-City (KR); Tae-Joon Kim, Yongin-city (KR)

(21) Appl. No.: 13/137,498

(22) Filed: Aug. 22, 2011

(30) Foreign Application Priority Data
Jan. 10, 2011 (KR) 10-2011-0002381

(51) Int. Cl. H05K 7/00

(52) U.S. Cl. 361/679.01

(57) ABSTRACT

A display device includes a display panel having at least one corner on a bent edge thereof, a frame on the display panel, and at least one air layer between the display panel and the frame. The frame supports the display panel, and the air layer corresponds to one corner of the display panel.

### RELATED APPLICATIONS

This application claims priority to and the benefit of Korean Patent Application No. 10-2011-0002381 filed in the Korean Intellectual Property Office on Jan. 10, 2011, the entire contents of which are incorporated herein by reference.

### BACKGROUND

A display device includes a display panel for displaying images. The display panel may have a quadrangular shape with four corners. As such, if an impact is imparted to the display device, stress focused on the corner of the display panel may break the display panel.

The above information disclosed in this Background section is only for enhancement of understanding of the background of the described technology and therefore it may contain information that does not form the prior art that is already known in this country to a person of ordinary skill in the art.

### SUMMARY

Embodiments may be realized by providing a display panel including at least one corner formed on a bent edge, a frame provided on the display panel and supporting the display panel, and at least one air layer provided between the display panel and the frame and formed to correspond to the corner.

The frame may face the corner with the air layer therebetween.

The corner may be floated from the frame.

The display device may include a tape provided between the display panel and the frame. The tape may include a chamfer formed to neighbor the air layer.

An end of the tape may be provided on the same line as an end of the display panel.

The frame may include a dent formed to be concave corresponding to the air layer.

The display panel may further include a first substrate including a pad area, and a second substrate facing the first substrate and exposing the pad area since it is smaller than the first substrate. The air layer may be provided to correspond to the pad area.

The frame may surround at least a part of the edge of the display panel.

The display panel may include at least one of a liquid crystal layer and an organic light emitting element.

### BRIEF DESCRIPTION OF THE DRAWINGS

Features will become apparent to those of ordinary skill in the art by describing in detail exemplary embodiments with reference to the attached drawings in which:

FIG. 1 illustrates a perspective view of a display device according to an exemplary embodiment.

FIG. 2 illustrates a magnified part A of the display device in FIG. 1.

FIG. 3 illustrates a display device excluding a display panel from FIG. 2.

FIG. 4 illustrates a cross-sectional view taken along a line IV-IV in FIG. 2.

FIG. 5 illustrates a cross-sectional view of a display device according to an exemplary embodiment.

### DETAILED DESCRIPTION

Korean Patent Application No. 10-2011-0002381, filed on Jan. 10, 2011, in the Korean Intellectual Property Office, and entitled: “Display Device,” is incorporated by reference herein in its entirety.

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the invention to those skilled in the art.

The drawings and description are to be regarded as illustrative in nature and not restrictive. Like reference numerals designate like elements throughout the specification.

Furthermore, in some exemplary embodiments, constituent elements having the same construction are assigned the same reference numerals and are described in connection with a first exemplary embodiment as a representative example. In the remaining exemplary embodiments, e.g., the second exemplary embodiment, only constituent elements different from those of the first exemplary embodiment are described.

The size and thickness of each component shown in the drawings are arbitrarily shown for understanding and ease of description, but the embodiments are not limited thereto. The thickness of layers, films, panels, regions, etc., in the drawings, may be exaggerated for clarity. For understanding and ease of description, the thicknesses of some layers and areas may be exaggerated. It will be understood that when an element such as a layer, film, region, or substrate is referred to as being “on” another element, it can be directly on the other element or intervening elements may also be present. In addition, “˜on” is either positioned on or below a portion of a target or positioned on the upper side based on a gravity direction, throughout the specification.

In addition, unless explicitly described to the contrary, the word “comprise” and variations such as “comprises” or “comprising” will be understood to imply the inclusion of stated elements but not the exclusion of any other elements.

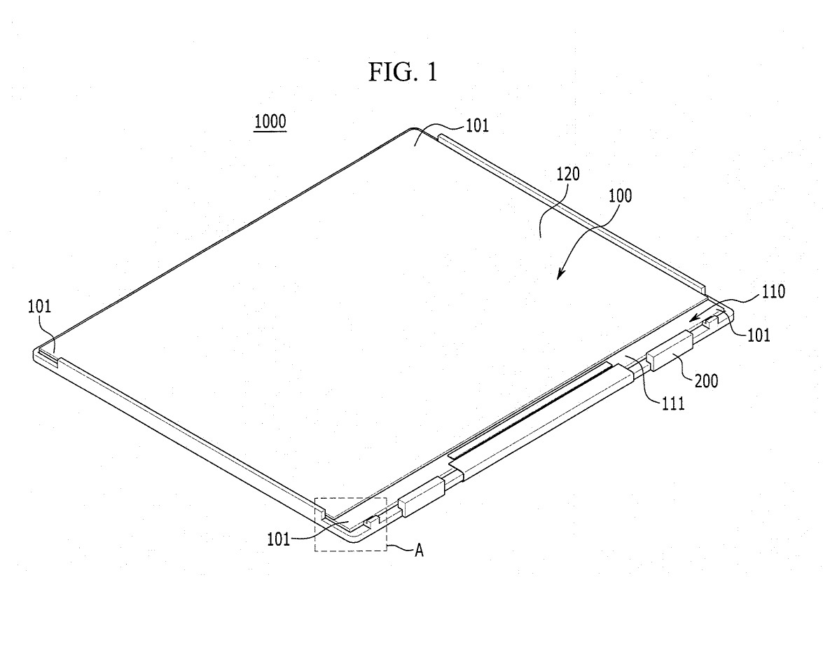

A display device according to a first exemplary embodiment will now be described with reference to FIG. 1 to FIG. 4.

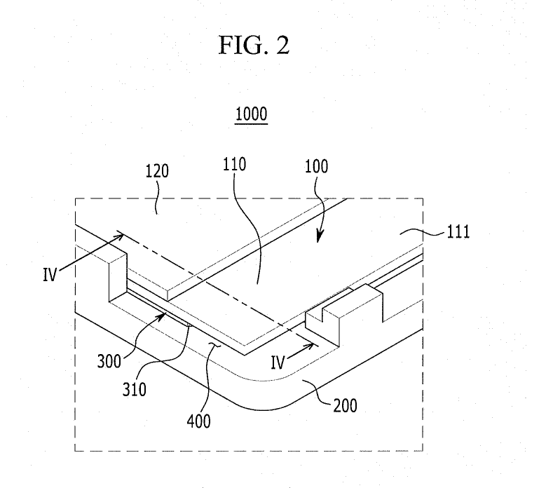

FIG. 1 illustrates a perspective view of a display device according to a first exemplary embodiment. FIG. 2 illustrates a magnified part A of FIG. 1.

As shown in FIG. 1 and FIG. 2, the display device 1000 may include a display panel 100, a frame 200, tape 300, and an air layer 400.

The display panel 100 may display an image and may have a quadrangular shape including four corners 101 formed on bent edges. The display panel 100 according to the first exemplary embodiment is illustrated as having a quadrangular shape. However, embodiments are not limited thereto. For example, the display panel 100 according to other exemplary embodiments may have a triangular, polygonal, or closed-loop shape with at least one corner formed on a bent edge.

The display panel 100 may include a liquid crystal layer (not shown). As such, the display panel 100 may display the image by using a liquid crystal layer (not shown) and light irradiated by a backlight unit (not shown). The display panel 100 may include an organic light emitting element (not shown), and may display the image by using light emitted by an organic light emitting element (not shown). However, embodiments are not limited thereto, e.g., the display panel 100 may be other direct or indirect light emitting elements. The display panel 100 may include a first substrate 110 and a second substrate 120 facing each other with a liquid crystal layer (not shown) or an organic light emitting element (not shown) therebetween.

The first substrate 110 may include a pad area 111. A flexible printed circuit board (FPCB) and/or a printed circuit board (PCB) may be connected, e.g., directly connected, to a pad in the pad area 111. The pad area 111 may be formed on the first substrate 110 and may be adjacent to the second substrate 120 that is smaller than the first substrate 110. For example, the second substrate 120 may be smaller than the first substrate 110, and may expose the pad area 111. The second substrate 120 may be smaller than the first substrate 110 by an amount substantially equal to the area of the pad area 111. A wire electrically connected to the pad formed in the pad area 111 may be formed on at least one of the first substrate 110 and the second substrate 120, and the liquid crystal layer (not shown) or the organic light emitting element (not shown) included in the display panel 100 may be driven by the wire.

A polarizing plate for, e.g., converting the optical axis of the light irradiated to the display panel 100 and/or light provided to the outside through the display panel 100, may be attached to at least one of the front or the rear of the display panel 100. A backlight unit (not shown) for irradiating light to the display panel 100 may be provided on the rear of the display panel 100.

The display panel 100 may include at least one of the liquid crystal layer (not shown) and the organic light emitting element (not shown), and the display panel according to the embodiment is not restricted to this and it can be a flat display panel for displaying the image in various ways in a like manner of, e.g., the plasma display panel (PDP).

The frame 200 may be provided in the display panel 1000. The frame 200 may support the display panel 100 such that the display panel 100 is seated inside the frame 200.

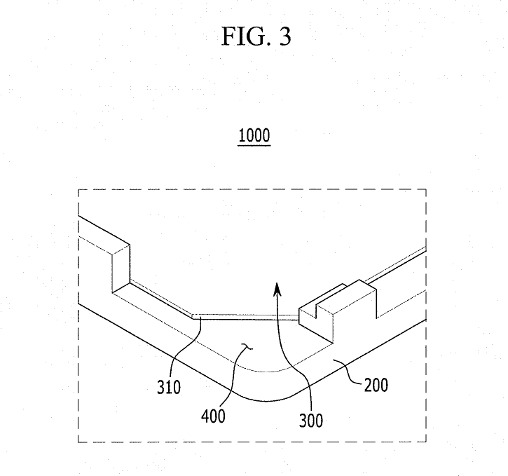

FIG. 3 illustrates a display device without the display panel from FIG. 2.

As shown in FIG. 1 to FIG. 3, the frame 200 may be larger than the display panel 100, and may surround at least a part of the edge of the display panel 100. The frame 200 may face the display panel 100 with the tape 300 therebetween. The frame 200 may be attached to the display panel 100 by the tape 300 to support the display panel 100. When the display device 1000 includes the backlight unit (not shown), the center of the frame 200 may be opened, and the backlight unit (not shown) may be formed in the opened center. For example, the center of the frame 200 may include an opening corresponding to the backlight unit.

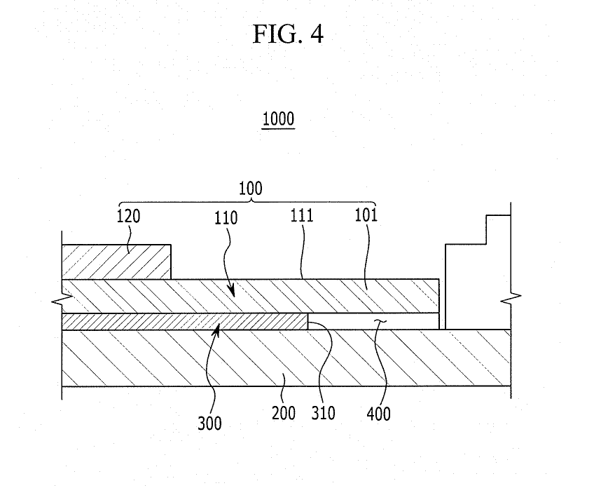

FIG. 4 illustrates a cross-sectional view of FIG. 2 taken along a line IV-IV.

As shown in FIG. 3 and FIG. 4, the tape 300 may be provided between the display panel 100 and the frame 200. The tape 300 may attach the display panel 100 and the frame 200 together. The tape 300 may have an edge that corresponds to the edge of the display panel 100 to attach the display panel 100 and the frame 200 together so an end of the tape 300 is provided on the same line of the display panel 100. The tape 300 may include a chamfer 310 corresponding to a corner 101 of the display panel 100. The chamfer 310 may be a beveled edge of the tape 3 that is spaced apart from the corner 101 of the display panel 100. The chamfer 310 may be formed to correspond to the corner 101 of the display panel 100 so the corner 101 of the display panel 100 is floated from the frame 200, e.g., the tape 300 may be excluded in an area below the corner 101. That is, an air layer 400 may be formed between the corner 101 of the display panel 100 and the frame 200, and the chamfer 310 is formed to neighbor the air layer 400.

The air layer 400 may be provided between the display panel 100 and the frame 200 and is formed to correspond to the corner 101. The corner 101 may be spaced apart from the frame 200 by the air layer 400. Since the air layer 400 is provided between the corner 101 of the display panel 100 and the frame 200, the frame 200 may face the corner 101 with the air layer 400 therebetween.

The air layer 400 may be provided on, e.g., below, all the corners of a display device, e.g., all the four corners 101 of the display panel 100. The air layer 400 may be provided on, e.g., below, only some of the corners of the display device. For example, the air layer 400 may be provided below the two corners 101 of the display panel 100 provided in the pad area 111. The two corners 101 of the display panel 100 provided in the pad area 111 of the display panel 100 on which the first substrate 110 is provided are thinner than the other corners 101 of the display panel 100 on which the first substrate 110 and the second substrate 120 are provided. Accordingly, it is desirable for the air layer 400 to be provided on the two corners 101 of the display panel 100 provided in the pad area 111 to suppress breakage of the corners 101.

Accordingly, the corner 101 of the display panel 100 may be floated from the frame 200 by the air layer 400 so the corner 101 of the display panel 100 may be protected and/or prevented from being broken by, e.g., stress concentrated on the corner 101 of the display panel 100 when an impact is applied to the display device 1000 from the outside. For example, when stress is focused on the corner 101 of the display panel 100 by the externally applied impact, breakage of the corner 101 may be suppressed since the corner 101 of the display panel 100 that is floated from the frame 200 is not directly interfered with by the frame 200.

Accordingly, the display device 1000 according to the first exemplary embodiment may form the air layer 400 between the display panel 100 and the frame 200 in correspondence to the corner 101 of the display panel 100, thereby breakage of the corner 101 of the display panel 100 because of, e.g., an impact, may be suppressed.

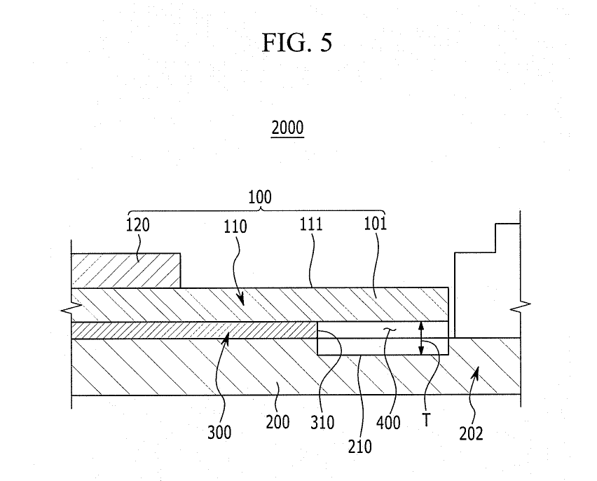

Referring to FIG. 5, a display device according to a second exemplary embodiment will now be described.

FIG. 5 illustrates a cross-sectional view of a display device according to the exemplary embodiment. As shown in FIG. 5, the frame 202 of the display device 2000 may further include a dent 210.

The dent 210 may be formed to be concave portion corresponding to the corner 101 of the display panel 100. Accordingly, the dent 210 may be formed to be dented, e.g., to form a trench, on the surface of the frame 202 so the air layer 400 is formed between the corner 101 of the display panel 100 and the dent 210 of the frame 202.

Hence, the display device 2000 according to the second exemplary embodiment may variably set the thickness (T) of the air layer 400 depending on the thickness of the tape 300 and the thickness of the dent 210 can form the air layer 400 to be thicker than that in the display device 1000 according to the first exemplary embodiment. The dent 210 may function as a factor for floating the corner 101 of the display panel 100 to be higher than the frame 202 and may stably suppress breakage of the corner 101 of the display panel 100 by, e.g., external impact.

By way of summation and review, a display device may include a display panel, a frame for supporting the display panel, and tape between the display panel and the frame that attaches the display panel and the frame together.

However, the display panel of the display device may have a quadrangular shape with four corners or a polygonal shape with a plurality of corners so if an impact is imparted to the display device, stress focused on the corner of the display panel may break the display panel.

Embodiments, as discussed above, relate to display devices including a frame for, e.g., supporting a display panel. Embodiments relate to an effort to provide a display device having the features of suppressing breakage of a corner of a display panel. That is, according to exemplary embodiments, breakage of a corner of a display panel in a display device may be suppressed.

Exemplary embodiments have been disclosed herein, and although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

What is claimed is:

1. A display device, comprising:
a display panel having at least one corner on a bent edge thereof;
a frame on the display panel, the frame supporting the display panel; and
at least one air layer between the display panel and the frame, the air layer corresponding to the one corner of the display panel.

2. The display device of claim 1, wherein the frame faces the one corner and the air layer is between the frame and the one corner.

3. The display device of claim 1, wherein the one corner is floated above the frame.

4. The display device of claim 1, further comprising a tape between the display panel and the frame, the tape including a chamfer adjacent to the air layer.

5. The display device of claim 4, wherein an end of the tape is on a same line as an end of the display panel.

6. The display device of claim 1, wherein the frame includes a concave dent that corresponds to the air layer.

7. The display device of claim 1, wherein the display panel further includes:
a first substrate including a pad area, the air layer corresponding to the pad area; and
a second substrate smaller than the first substrate, the second substrate facing the first substrate and exposing the pad area.

8. The display device of claim 1, wherein the frame surrounds at least a portion of the bent edge of the display panel.

9. The display device of claim 1, wherein the display panel includes one of a liquid crystal layer and an organic light emitting element.
